(19) United States
(12) Patent Application Publication
(10) Pub. No.: US 2008/0220550 A1
(43) Pub. Date: Sep. 11, 2008

(54) METHOD OF PRODUCING N-TYPE GROUP-13 NITRIDE SEMICONDUCTOR, METHOD OF FORMING CURRENT CONFINEMENT LAYER, METHOD OF PRODUCING SURFACE EMITTING LASER, METHOD OF CHANGING RESISTANCE OF NITRIDE SEMICONDUCTOR AND METHOD OF PRODUCING SEMICONDUCTOR LASER

(75) Inventor: Yoshinori Tomida, Atsugi-shi (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, Tokyo (JP)

(21) Appl. No.: 12/041,531

(22) Filed: Mar. 3, 2008

(30) Foreign Application Priority Data
Mar. 8, 2007 (JP) 2007-058607

(51) Int. Cl. H01L 21/02

(52) U.S. Cl. 438/29; 438/795; 438/38; 257/E21.002

(57) ABSTRACT

The object of the present invention is to provide a method of producing an n-type group-13 nitride semiconductor which enables resistance of the n-type group-13 nitride semiconductor to be changed, as well as, a method of producing a laser using the above method to produce a current confinement structure. There is provided a method of producing an n-type group-13 nitride semiconductor, including: preparing an n-type group-13 nitride semiconductor; and irradiating the n-type group-13 nitride semiconductor with light having a wavelength of 350 nm or more to 370 nm or less so as not to change a crystal structure of the n-type group-13 nitride semiconductor before and after the light irradiation, thereby increasing resistance of the n-type group-13 nitride semiconductor.

### BACKGROUND OF THE INVENTION

1. Field of the Invention

The present invention relates to a method of producing an n-type group-13 nitride semiconductor, method of forming a current confinement structure, a method of producing a surface emitting laser, a method of changing the resistance of nitride semiconductors and a method of producing a semiconductor laser

2. Description of the Related Art

In the case where a GaAs semiconductor material is used in production of a laser having a current confinement structure, the production method has been conventionally as follows. Specifically, AlAs is used as a multi-layer film that constitutes the laser. And a mesa structure is formed. The AlAs layer exposed to a side face of the mesa structure is selectively oxidized using water vapor or the like. During the oxidization, Al₂O₃ is formed on the selectively oxidized region. The electric resistance of the Al₂O₃ portion is higher than that of the current injection portion (AlAs) and thus, the Al₂O₃ portion comes to be a current confinement portion.

In the case where a group-13 nitride semiconductor material, represented by a GaN, is used, it is difficult to oxidize selectively a specified layer alone, unlike AlAs. Japanese Patent Application Laid-Open No. H11-261160 discloses a method of forming a current confinement structure in a group-13 nitride multi-layer film. The schematic view of a structure formed by the method is illustrated in FIG. 13. The structure is of a non-planar type.

In FIG. 13, the structure includes a semiconductor laser device 100, a substrate 101, a buffer layer 102, an n-type contact layer 103, an n-type first cladding layer 104 and an active layer 105, and also a p-type etching stop layer 106, a p-type second cladding layer 107, a current confinement layer 108, a p-type contact layer 109, an n-type electrode 110 and a p-type electrode 111.

First, the n-type first cladding layer 104 and the active layer 105 are formed by epitaxial growth. Then, a layer for a current confinement structure is formed and a region which is to be current injection portion 120 (opening) is formed by wet etching process. And the region not having been etched is to be a current confinement portion 108. After that, the p-type second cladding layer 107 is formed again by epitaxial growth (re-growth).

In the case where a current confinement structure is formed by the method using re-growth, the crystal quality before and after the re-growth may deteriorate. Furthermore, the distribution of acceptor impurity concentration at the opening becomes non-uniform, which may result in poor electrical properties.

Alternatively a current confinement structure is formed by irradiating a planar-type group-13 nitride semiconductor with light. Irradiating a semiconductor with light having a wavelength of absorption band can mainly cause two types of reactions: reaction not involving a change of crystal structure and reaction involving a change of crystal structure.

First, methods of causing reaction which is not accompanied by a change of crystal structure will be described. One of the methods is low-temperature annealing. Jpn. J. Appl. Phys. Vol. 31 (1992), pp 1258-1266 discloses a method of changing resistance by low-temperature annealing. In the method, first p-type gallium nitride (GaN) film is formed by epitaxial growth. Immediately after the film formation, the resistivity of the film is about 10⁶ Ω·cm. Then, the film is annealed at 700 to 800° C. The resistivity after the annealing is several Ω·cm (refer to FIG. 7). Further, Japanese Patent Application Laid-Open No. H08-222797 discloses a method of decreasing the resistance at the opening using the reaction which is not accompanied by a change of crystal structure.

On the other hand, one of the methods of causing the reaction which is accompanied by a change of crystal structure is to irradiate a p-type gallium nitride with high-power laser light. Japanese Patent Application Laid-Open No. 2004-165436 discloses a method of increasing the resistance of a p-type gallium nitride in which the crystal structure of the p-type gallium nitride is changed to amorphous by the irradiation with high-power laser light so as to increase the resistance of the irradiated portion. The region of the current confinement layer other than the opening portion of the same, as a current confinement portion, is irradiated uniformly with high-power laser light. The region irradiated to the laser light is changed to amorphous to increase the resistance.

Generally, however, when changing crystal structure to amorphous, the lattice constant of the crystal is changed, which results in a change in volume. This sometimes damages the active layer or the cladding layer thermally, mechanically or optically and may result in inferior device performances.

Furthermore, Phys. Stat sol (c) 0 No. 6 1627-1650 (2003) (refer to FIG. 8) and Wataru UTSUMI et al. “Congruent melting of gallium nitride at high pressure,” Spring-8 User Experiment Report 2004. 01, pp 42, Synchroton Radiation Research Center, Japan Atomic Energy Research Institute Kansai Research Establishment (refer to FIG. 9) discloses that heating gallium nitride to 800° C. or higher at atmospheric pressure causes an irreversible reaction that decomposes the gallium nitride into gallium nitride liquid and nitrogen gas.

### SUMMARY OF THE INVENTION

As described above, it has been known that the resistance of a p-type GaN film can be changed by a specified technique. The present inventor has directed tremendous research effort toward changing the resistance of an n-type GaN and has found that an n-type GaN is partly enabled to have increased resistance by a specified treatment. And he finally has made the present invention.

The object of the present invention is to provide a method of producing an n-type group-13 nitride semiconductor which enables the resistance of the n-type group-13 nitride semiconductor to be changed and a method of producing a laser which uses the above method to form the current confinement structure.

The method of producing an n-type group-13 nitride semiconductor of the present invention includes: preparing an n-type group-13 nitride semiconductor; and irradiating the n-type group-13 nitride semiconductor with light having a wavelength of 350 nm or more to 370 nm or less so as not to change the crystal structure of the n-type group-13 nitride semiconductor before and after the light irradiation, thereby increasing resistance of the n-type group-13 nitride semiconductor.

The method of forming a current confinement structure of the present invention includes: preparing a layer including an n-type group-13 nitride semiconductor; and irradiating a region of the layer including an n-type group-13 nitride semiconductor, as a current confinement portion, with light having a wavelength of 350 nm or more to 370 nm or less which the current confinement portion has resistance higher than that of the current confinement opening as a region through which current is injected into an active layer, and the crystal structure is not changed after the light irradiation.

The present invention enables an n-type group-13 nitride semiconductor to have an increased resistance by light irradiation without substantially changing the crystal structure of the n-type group-13 nitride semiconductor.

The term “group-13 nitride semiconductor” means B, Al, Ga, In or TI in the periodic table. The term “group 13 elements” corresponds to group 3B elements in the old periodic table.

Further features of the present invention will become apparent from the following description of exemplary embodiments with reference to the attached drawings.

### BRIEF DESCRIPTION OF THE DRAWINGS

FIG. 1 is a cross-sectional view illustrating the structure of a surface emitting laser according to an embodiment of the present invention.

FIG. 2 is a cross-sectional view of a surface emitting laser illustrating the method of forming a current confinement structure of a surface emitting laser according to an embodiment of the present invention.

FIG. 3 is a cross-sectional view of a surface emitting laser illustrating the method of forming a current confinement structure of a surface emitting laser according to an embodiment of the present invention.

FIG. 4 is a cross-sectional view of a surface emitting laser illustrating the method of forming a current confinement structure of a surface emitting laser according to an embodiment of the present invention.

FIG. 5 is a cross-sectional view of a surface emitting laser illustrating one example of structure where a sapphire substrate is used in the embodiment of the present invention.

FIG. 6 is a graph illustrating the relation between the amount of the 355 nm laser light with which the n-type group-13 nitride semiconductor is irradiated and the resistivity of the n-type group-13 nitride semiconductor in the embodiment of the present invention.

FIG. 7 is a graph illustrating the resistance change of a p-type gallium nitride described in Jpn. J. Appl. Phys. Vol. 31 (1992) pp 1258-1266.

FIG. 8 is a graph illustrating the threshold of the decomposition temperature of gallium nitride described in Phys. Stat sol (c) 0 No. 6 1627-1650 (2003).

FIG. 9 is a phase diagram of the gallium nitride described in Wataru UTSUMI et al. “Congruent melting of gallium nitride at high pressure,” Spring-8 User Experiment Report 2004. 01, pp 42, Synchroton Radiation Research Center, Japan Atomic Energy Research Institute Kansai Research Establishment.

FIG. 10 is a graph illustrating the absorption coefficient of gallium nitride near the forbidden band.

FIG. 11 is a graph illustrating the threshold of the laser energy density of gallium nitride decomposition described in Phys. Stat sol (c) 0 No. 6 1627-1650 (2003).

FIG. 12 is a graph illustrating the rocking curve of gallium nitride obtained by laser exposure according to an embodiment of the present invention.

FIG. 13 is a view illustrating prior art.

### DESCRIPTION OF THE EMBODIMENTS

The present invention, as described above, enables an n-type group-13 nitride semiconductor to have increased resistance without substantially damaging its crystal structure. This is attributable to the present inventor's finding the phenomenon that the electrical resistance of the crystal structure is increased by exposing the n-type group-13 nitride semiconductor to laser light having an energy density within the range that does not substantially damage the crystal structure.

The wording “does not substantially damage the crystal structure” mean that the rocking curve does not substantially change before and after irradiating the crystal structure with light. For example, when the change in half width of rocking curve is within 10 percent, the crystal structure is considered not being substantially damaged. The details of this will be described later.

A group-13 nitride semiconductor becomes an n-type group-13 nitride semiconductor when doped with a group-14 (group 4B) element such as Si. For example, gallium nitride can be doped with a group-14 element to the extent that the carrier density per cm³ becomes about 10²¹. The resistivity of the gallium nitride thus doped is about 10⁻² to 10⁻³ Ω·cm.

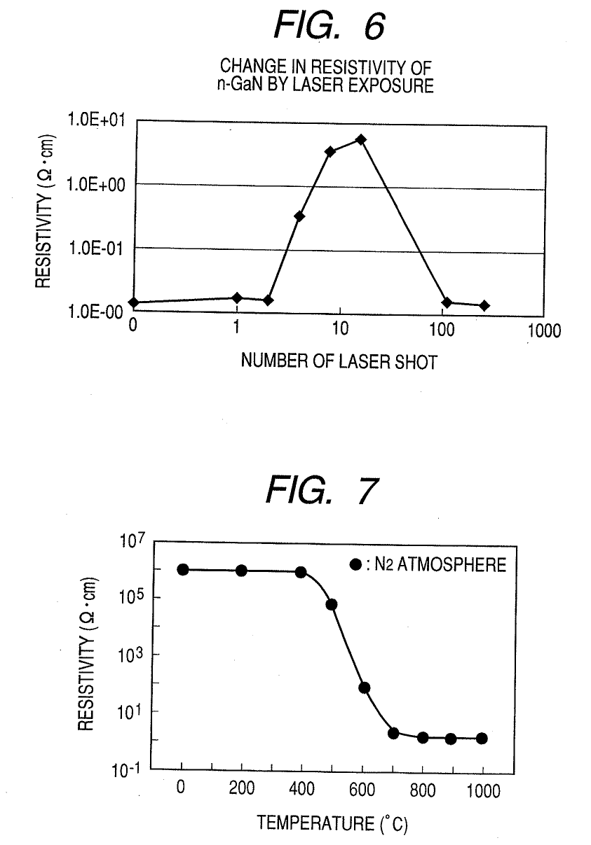

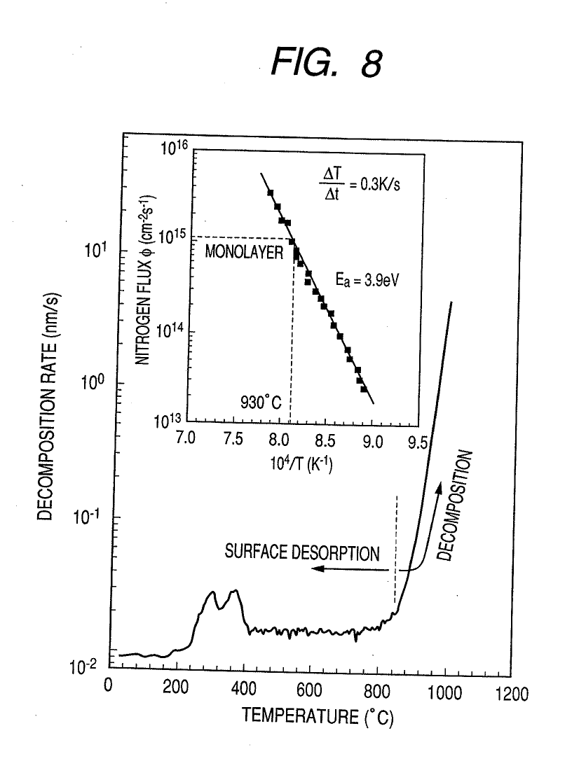

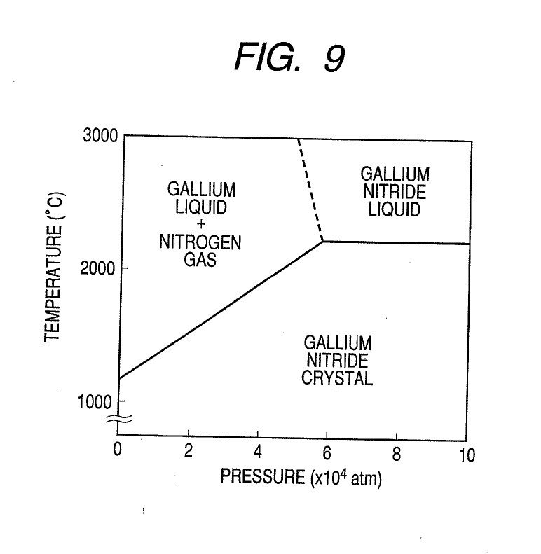

FIG. 6 illustrates the results of the observation of the resistance changes with laser pulse, when irradiating an n-type gallium nitride with laser light, at the irradiated portion of the n-type gallium nitride. The laser used for irradiation was as follows: wavelength was 355 nm (YAG THG), energy density was 50 mJ/cm² and pulse width was 5 ns. It was observed that the resistance reached as high as two digits or more at a laser pulse of about 8 to 10.

In the present invention, the current confinement is done in an n-type group-13 nitride utilizing the above resistance changes. The finding described above enables the n-type current confinement layer of an epitaxially-grown planar type group-13 nitride semiconductor to have increased resistance by light irradiation so as to form a current confinement structure.

Furthermore, a surface emitting laser having the following characteristics can be realized by utilizing the above findings.

(1) The contact layer, as the surface of the surface emitting laser, and current confinement layer include n-type group-13 nitride semiconductor. In such a construction, a sufficient amount of current can be supplied to the active layer by the current confinement effect. This provides a surface emitting laser that oscillates at low threshold and has a high light emitting efficiency.

(2) The crystallinity of the contact layer, cladding layer, active layer and current confinement layer opening all adjacent to the current confinement portion does not deteriorate largely when the current confinement structure is allowed to have increased resistance, because the increase in resistance does not involve crystal structure changes. Thus, good device performances can be obtained.

(3) The surface emitting laser is a planar type one in which heat radiation is easy; thus, it can decrease the effect of heat generation accompanied by current injection, compared with a laser diode having a mesa structure.

(4) The surface emitting laser has a planar structure, which makes easier the process of forming a photonic crystal structure or forming an electrode.

In the following, the foregoing will be described in detail.

Isamu AKASAKI (eds): Group Ill-V Nitride Semiconductors, (Baihukan) discloses that the forbidden band width (band gap) of group-13 nitride semiconductors AlₓGa₁₋ₓN is given by the following expression using composition ratio x (1):

εg(Γ)=3.39+1.81x+bx²(b=1.0±0.3, 0≦x≦0.4) (1)

wherein εg(Γ) represents band gap.

In the case where wavelength λ is used to express εg(Γ), εg(Γ)=hc/λ, wherein h represents Planck's constant and c light velocity. Thus, εg(Γ) can be converted to wavelength. And the wavelength converted from the forbidden band width is sometimes referred to as forbidden band wavelength. As is apparent from the above expression, εg(Γ) and wavelength inversely proportional to each other.

When the energy of the laser light with which a group-13 nitride is irradiated is larger than εg(Γ), the laser light transmit the group-13 nitride, whereas when the energy of the laser light with which a group-13 nitride is irradiated is smaller than εg(Γ), the laser light is absorbed by the group-13 nitride.

When the wavelength of the laser light with which a group-13 nitride is irradiated is shorter than the forbidden band wavelength λ, the laser light passes through the group-13 nitride, whereas when the wavelength of the laser light with which a group-13 nitride is irradiated is longer than the forbidden band wavelength λ, the laser light is absorbed by the group-13 nitride.

For group-13 nitrides, bandwidth of the forbidden band wavelength lies in the ultraviolet wavelength band. Thus, ultraviolet laser is suitably used as a laser for material processing.

Furthermore, a group-13 nitride semiconductor has a steep absorption edge, because it has a direct transition-type band structure, and a light absorption coefficient is as high as about 10⁴ to 10⁵/cm. Accordingly, if a suitable composition and a suitable laser wavelength are combined, the current confinement layer is allowed to selectively absorb light.

One example of composition tables of epitaxially grown films is shown in Table 1.

TABLE 1

| | | | | | | Com- |
|---|---|---|---|---|---|---|
| layer | Repeat | Material | Compos_x | Eg (eV) | λ(nm) | ment |
| 14 | | AlxGa1-xN | 0.10 | 3.58 | 346 | n |
| Absorb | | GaN | | 3.39 | 366 | n |
| 13 | | GaxIn1-xN | 0.98 | 3.35 | 370 | |
| 12 | | GaxIn1-xN | 0.85 | 3.07 | 404 | QW |
| 11 | | GaxIn1-xN | 0.98 | 3.35 | 370 | |
| 10 | | GaxIn1-xN | 0.85 | 3.07 | 404 | QW |
| 9 | | GaxIn1-xN | 0.98 | 3.35 | 370 | |
| 8 | | AlxGa1-xN | 0.07 | 3.52 | 352 | p |
| 7 | | n⁺⁺ | | | | TJ |
| | | p⁺⁺ | | | | |
| 6 | 35 | AlxGa1-xN | 0.34 > 0.00 | 3.76 | 330 | DBR |
| 5 | | AlxGa1-xN | 0.34 | 4.12 | 301 | |
| 4 | | AlxGa1-xN | 0.00 > 0.34 | 3.76 | 330 | |
| 3 | | GaN | | 3.39 | 366 | |
| 2 | | GaN | | 3.39 | 366 | |
| 1 | | GaN | | 3.39 | 366 | |

Suppose that an epitaxial film having a composition shown in Table 1 is irradiated with laser light having a wavelength of 355 nm. The forbidden band wavelength (346 nm) of the n-type contact layer (Layer 14) is shorter than 355 nm. Thus, the laser light substantially passes through the n-type contact layer. The resistivity of the n-type contact layer after laser irradiation is of the order of 10⁻² Ω·cm, which is almost the same as the resistivity before laser irradiation.

In contrast, the forbidden band wavelength (366 nm) of the current confinement layer (absorb) is longer than 355 nm. Thus, the laser light is absorbed by the current confinement layer. Furthermore, the absorption coefficient of gallium nitride is relatively high, about 10⁴ to 10⁵/cm. Thus, the laser light is almost completely absorbed by, for example, the current confinement layer having a thickness of 400 nm. In that case, the cladding layer and the active layer are hardly damaged.

According to Phys. Stat sol (c) 0 No. 6 1627-1650 (2003), in decomposition reaction by laser light having a wavelength of 355 nm, the point of damage onset is observed when the energy density is higher than 200 mJ/cm², as shown in FIG. 11.

The present invention enables an n-type group-13 nitride to have increased resistance without damaging the crystal structure by irradiating the n-type group-13 nitride with laser light having an energy density equal to or lower than the point of damage onset.

That the crystal structure has not greatly changed can be verified even by the rocking curve measured using X-rays.

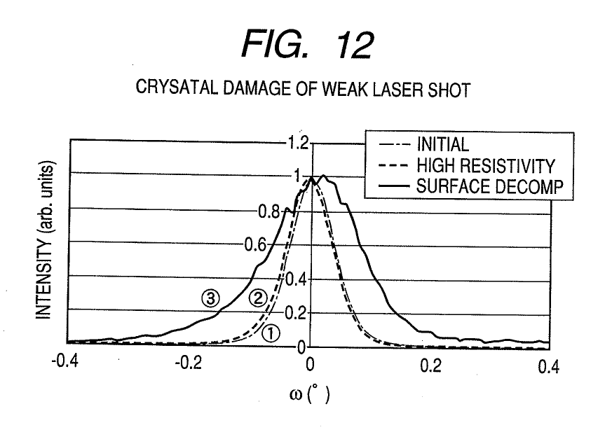

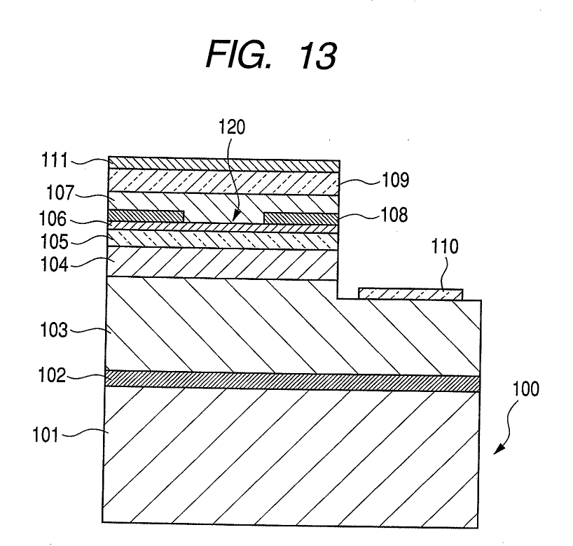

FIG. 12 is a graph for comparing the resistance state of n-type gallium nitride before light irradiation (Initial) (circle number 1), the resistance state of n-type gallium nitride after irradiation with light having an energy density equal to or lower than the point of damage onset (circle number 2), and the resistance state of n-type gallium nitride after irradiation with light having an energy density equal to or higher than the point of damage onset (circle number 3).

The crystal structure does not substantially change after irradiation with light having an energy density equal to or lower than the point of damage onset, because there is almost no shift of the rocking curve of circle number 1 relative to that of circle number 2. The crystal structure changes after irradiation with light having an energy density equal to or higher than the point of damage onset, because the half width of the rocking curve of circle number 3 is larger than that of the rocking curve of circle number 1. The phrase “the crystal structure is not substantially changed” used in the present invention mean the change (shift) of the rocking curve after light irradiation is 10% or less from the rocking curve before light irradiation. The rate of change can be estimated from the shifted amount of the peak value or of the half value of the peak value.

In the following a surface emitting laser including an n-type group-13 nitride semiconductor layer according to one embodiment of the present invention will be described.

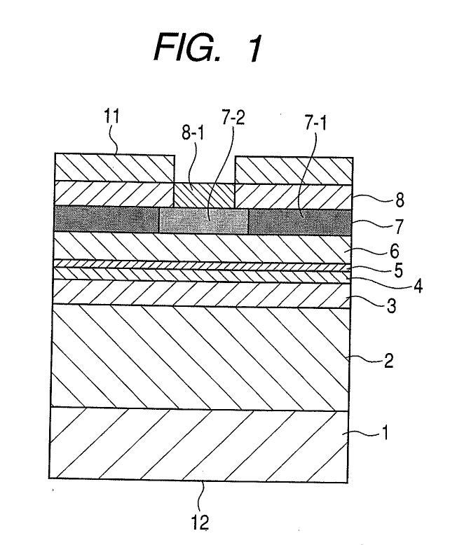

FIG. 1 is a schematic cross-sectional view illustrating the surface emitting laser according to the embodiment.

The surface emitting laser according to the embodiment includes: n-type group-13 nitride semiconductor DBR 2, tunnel junction 3, p-type cladding layer 4, quantum well active layer 5, n-type cladding layer 6, n-type group-13 nitride semiconductor current confinement layer 7 and n-type group-13 nitride semiconductor contact layer 8 which are stacked on the group-13 nitride substrate 1 in this order. And the surface emitting laser is provided with upper electrode 11 and lower electrode 12.

The n-type group-13 nitride semiconductor current confinement layer 7 includes: current confinement portion 7-1 whose resistance has been increased by irradiation with light having an energy density within the range that does not damage the crystal structure; and current confinement layer opening 7-2 whose resistance is lower than that of the current confinement portion 7-1. On the n-type group-13 nitride semiconductor current confinement layer 7, a current confinement layer which defines the current injection region (current confinement layer opening 7-2) for injecting current into active layer 5 is formed.

On contact layer 8, reflector 8-1 including photonic crystal is formed.

In the following a method of producing a surface emitting laser according to the embodiment will be described.

First, a substrate as a starting material is prepared by: forming a group-13 nitride substrate, by low temperature growth, on one of n-type gallium nitride substrate and sapphire substrate; and growing n-type gallium nitride epitaxially on the group-13 nitride substrate. All the crystal films are formed by epitaxial growth.

Then, n-type group-13 nitride semiconductor DBR (Distributed Bragg Reflector) 2 is formed on substrate 1 prepared as above.

DBR 2 is formed by stacking about 30 layers of AlₐGa₁₋ₐN each different in “a” composition and refractive index.

On DBR 2, tunnel junction 3, p-type Al_{b}Ga_{1-b}N layer 4 and an active layer of Ga_{c}In_{1-c}N having a double quantum well structure (quantum well active layer 5) are formed in this order.

And on n-type cladding layer 6 formed on the active layer 5, current confinement layer 7 of n-type AlₓGa₁₋ₓN (0≦x<0.4) and contact layer 8 of n-type Al_{x′}Ga_{1-x′}N (0≦x′<0.4 and x<x′) are formed in this order.

Thus, a surface emitting laser as shown in FIG. 1 is produced.

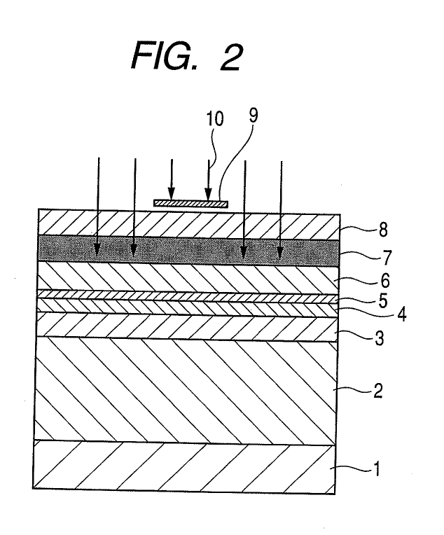

In the following a method of forming a current confinement structure will be described with reference to FIG. 2. In the method, a current confinement structure, which defines the current injection region for injecting current into the active layer 5, is formed by irradiation of light having an energy density within the range that does not damage the crystal structure.

For the n-type AlₓGa₁₋ₓN, which constitutes the current confinement layer 7, x is selected so that the band gap of the current confinement layer 7 is larger than that of the active layer 5 and smaller than that of the n-type contact layer, as the surface of the surface emitting laser.

Thus, the light emitted from the active layer is substantially transmitted and the laser light for material processing can be selectively absorbed by the current confinement layer.

In the planar-type group-13 nitride semiconductor produced by epitaxial growth as described above, a current confinement structure is formed as follows.

First, as shown in FIG. 2 light shield mask 9 is placed in the position where an current confinement layer opening is to be formed and the planar-type group-13 nitride semiconductor is exposed to laser light having a wavelength that is absorbed selectively by the n-type AlₓGa₁₋ₓN, which constitutes the above current confinement layer.

Suitably a laser which emits light having a wavelength of 350 nm or more to 370 nm or less is used as a laser for material processing.

For example, ultraviolet laser light obtained by subjecting YAG THG laser (355 nm) or XeF excimer laser (350 nm) light to nonlinear optical conversion can be used. It goes without saying that much more suitably a laser which emits light having a wavelength of 350 nm or more to 370 nm or less is used as a laser for material processing.

In the light exposure by a laser for material processing, is used light having an energy density within the range that does not change the crystal structure and having a wavelength equal to or longer than the forbidden band wavelength of the contact layer and equal to or shorter than the forbidden band wavelength of the current confinement layer. Suitably, the forbidden band wavelength of the current confinement layer is shorter than the forbidden band wavelength given by the following equation (1) and the forbidden band wavelength of the contact layer is longer than the forbidden band wavelength given by the following equation (2).

εg(Γ)=3.39+1.81x+bx²(b=1.0±0.3, 0≦x≦0.4) (1)

εg(Γ)=3.39+1.81x′+bx′²(b=1.0±0.3, 0<x′≦0.4) (2)

The range of the laser light energy density that does not change the crystal structure is determined by several parameters.

Such parameters include: the wavelength, monochromaticity, beam profile, pulse width, inter pulse period and pulse number of the laser for material processing used.

In case of a YAG THG (355 nm) laser with 5 ns pulse duration, suitably the energy density is 10 mJ/cm² or more to 200 mJ/cm² or less and particularly suitably 20 mJ/cm² or more to 100 mJ/cm² or less.

The film thickness of the current confinement layer used is suitably in the range of 100 nm to 1000 nm.

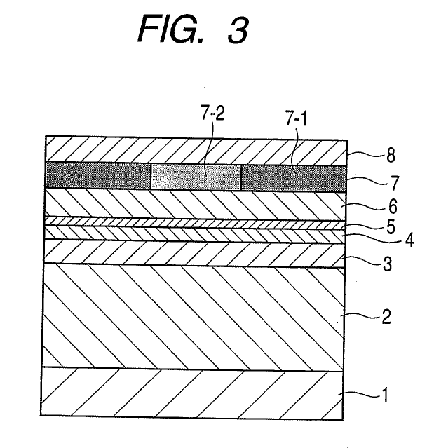

As shown in FIG. 3, the exposed region 7-1 is allowed to have a resistivity higher than that of the non-exposed region 7-2 by two digits due to the light exposure with the above laser for material processing. The non-exposed region 7-2 works as a current confinement layer opening that defines the current injection region for injecting current into the active layer 5 because its resistivity is lower than the resistivity of the exposed region 7-1.

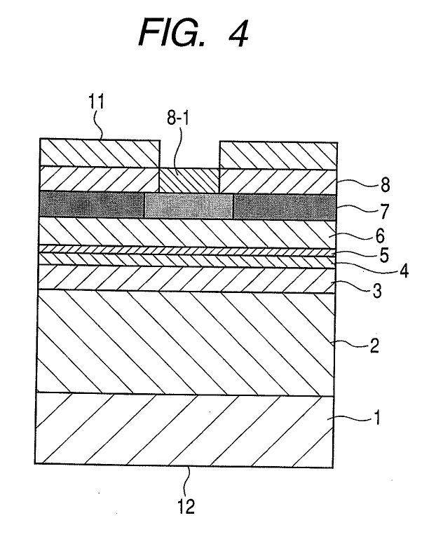

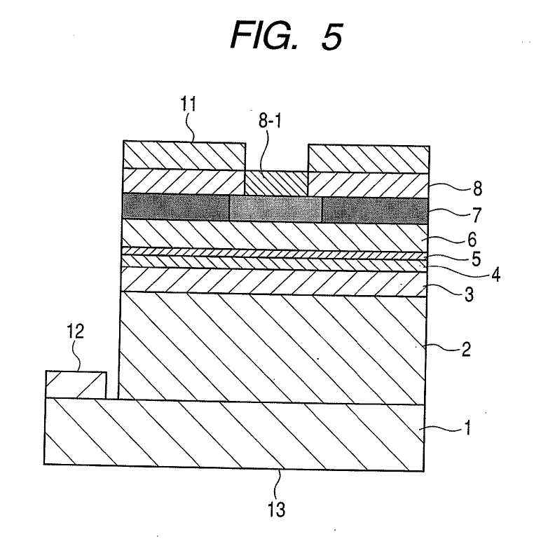

To enable light emitting at a low threshold level by the current injection, a reflector including a photonic crystal is formed above the current confinement layer opening, as shown in FIG. 4.

In this case, instead of forming a photonic crystal structure in the n-type contact layer, a reflector of n-type DBR layer may be formed in the electrode opening.

Electrode 11 is formed of metal or the like on the n-type contact layer 8 on the current confinement portion 7-1 and electrode 12 is formed also on the n-type group-13 nitride layer 1 on the substrate side.

In the case where sapphire substrate 13 is used in the embodiment, the n-type group-13 nitride layer 1 on the substrate side may be exposed by, for example, dry etching process so that electrode 12 may be formed on the exposed n-type group-13 nitride layer 1.

In the following the present invention will be described according to a method of changing the resistance of a nitride semiconductor as another embodiment.

Specifically an n-type nitride semiconductor (GaN, AlGaN or AlN) is irradiated with light having a wavelength of 350 nm or more to 370 nm or less so as to change the resistance of the same. Irradiation using the light in the above wavelength range is performed so that the cumulative light energy density becomes 10 mJ/cm2 or more to 200 mJ/cm² or less. Such irradiation enables the resistance of the irradiated portion to be increased selectively, therefore, is applicable to a current confinement layer and the like.

The present invention will be described in terms of a method of producing a semiconductor laser as still another embodiment. The method includes the following three steps:

(a) a step of preparing, on a substrate, a member comprising a first mirror, an active layer and an n-type group-13 nitride semiconductor layer;

(b) a step of forming a current confinement region by irradiating the n-type group-13 nitride semiconductor layer with light having a wavelength of 350 nm or more to 370 nm or less; and

(c) a step of forming a second mirror on the n-type group-13 nitride semiconductor layer.

The above steps (b) and (c) can be in reverse order. The first mirror is suitably a so-called DBR mirror. For the second mirror, not only a DBR mirror but a photonic crystal can be utilized. The irradiation using light having the specified wavelength described above is suitably performed so that the cumulative light energy density becomes 10 mJ/cm² or more to 200 mJ/cm² or less. Doing this enables part of the n-type group-13 nitride semiconductor layer to have increased resistance without substantially changing the crystal structure, thereby enabling the same to be utilized as a region for current confinement.

When changing the resistance of the group-13 nitride semiconductor used for the current confinement layer, it is suitable to use reaction that is not accompanied by a change of crystal structure. Because, if reaction accompanied by a change of crystal structure is used, irradiation of high power laser light damages the crystal structure and annealing at 800° C. or higher generates a nitride gas. In this case, a method is suitably used in which the region other than the opening is irradiated with light so as to increase the resistance of the irradiated region without causing a substantial change in the crystal structure of the layer. Such a method, however, had not been found yet.

For surface emitting lasers that include a contact layer formed using p-type gallium nitride, their threshold voltages are high. High threshold voltage can sometimes cause the problem of heat generation, resulting in poor laser oscillation. The high threshold voltage is largely attributed to the high resistance of p-type gallium nitride.

To lower the threshold voltage, it is desirable to make the resistance of the semiconductor used for the contact layer as low as possible. Furthermore, it is preferable to make the semiconductor used for the contact layer and the semiconductor used for the current confinement layer a uniform crystallinity.

The resistance of n-type gallium nitride, however, is lower than that of p-type gallium nitride. And in the case where an n-type group-13 nitride semiconductor is used for the current confinement layer of a surface emitting laser, the current confinement portion is formed as follows. Specifically, to make the resistance of the current confinement layer opening, as a current confinement portion, relatively low, the resistance of the region other than the opening is made high.

In the following, Examples of the present invention will be described.

### EXAMPLE 1

n-Type gallium nitride substrates of 2 inches in size were obtained from several manufacturers and subjected to epitaxial growth using the composition ratios shown in Table 1.

The thickness obtained by epitaxial growth was optimized by oscillation wavelength. The Layer 14 and the Absorb layer, which are the characteristics of the present invention, were grown to 100 nm and 400 nm, respectively.

A light shield mask was formed on a region, which is to be a current confinement layer opening, of the surface of the n-type AlGaN contact layer, shown by Layer 14, and the Layer 14 was irradiated with light of YAG THG laser as a laser for material processing. Beam profile was shaped into a flattop profile by an optical system under the laser conditions of wavelength: 355 nm, pulse width: 5 nanoseconds, repeat frequency: 10 Hz, and energy density: 50 mJ/cm². The monochromaticity of YAG THG laser light is high and controlled to be within the range of ±0.1 nm.

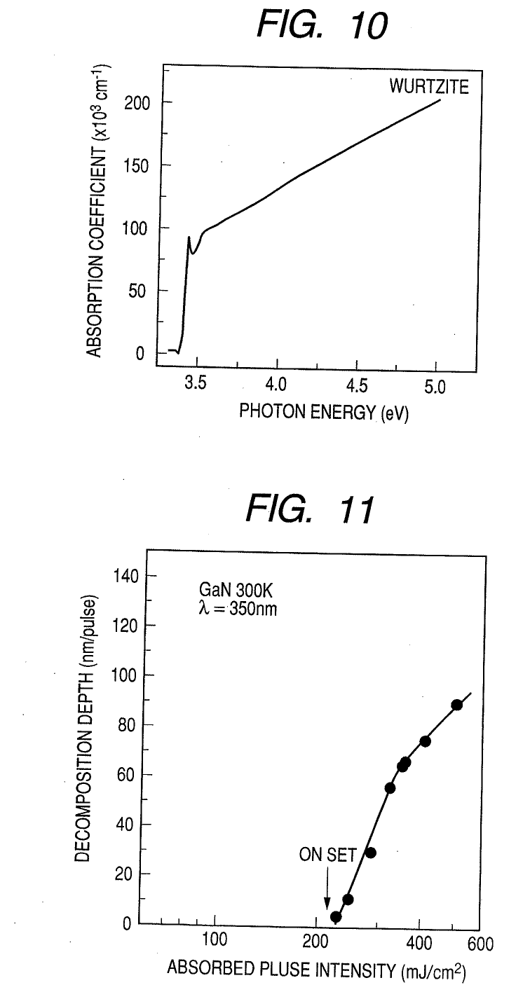

For the n-type AlGaN contact layer, expressed by Layer 14, which includes crystal with composition ratio shown in Table 1, the forbidden band is 3.54 eV and the rising of the absorption edge is steep, as shown in FIG. 10, because the n-type AlGaN is a direct band gap semiconductor.

Thus, the absorption at 355 nm (3.49 eV) is substantially zero. In contrast, for the forbidden band of the n-type GaN current confinement layer, expressed by Absorb, the forbidden band is 3.39 eV and the absorption coefficient at 355 nm is 10⁵.

Accordingly, 98% of the light having entered into the n-type GaN current confinement layer is absorbed in the inside of the current confinement layer.

A current confinement structure was formed by irradiating laser for material processing performing with eight-pulse in the timing of repeat frequency at 10 Hz to increase the resistance of the irradiated portion of the current confinement layer.

An upper mirror was formed by removing the light shield mask and forming a photonic structure by dry etching process.

The period “a” of the photonic structure was 200 nm to 300 nm and the hole radius r was 0.2 a to 0.5 a.

A ring-shaped metal electrode was formed around the photonic crystal mirror and a metal electrode was formed on the whole surface of the n-type gallium nitride substrate.

### EXAMPLE 2

A semiconductor laser was produced under the same conditions as in Example 1 except that an XeF excimer laser was used as a laser for material processing.

The laser conditions were as follows: wavelength 351±0.1 nm, pulse width 20 nanoseconds, repeat frequency 10 Hz, energy density 40 mJ/cm².

### EXAMPLE 3

A semiconductor laser was produced under the same conditions as in Example 1 except that a nitrogen laser was used as a laser for material processing and an n-type Al_{0.2}Ga_{0.8}N (Eg=3.79 eV=327 nm) was used for the contact layer.

The laser conditions were as follows: wavelength 337±0.1 nm, pulse width 4 nanoseconds, repeat frequency 10 Hz, energy density 20 mJ/cm².

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2007-058607, filed Mar. 8, 2007, which is hereby incorporated by reference herein in its entirety.

What is claimed is:

1. A method of producing an n-type group-13 nitride semiconductor, comprising:
preparing an n-type group-13 nitride semiconductor; and
irradiating the n-type group-13 nitride semiconductor with light having a wavelength of 350 nm or more to 370 nm or less so as not to change the crystal structure of the n-type group-13 nitride semiconductor before and after the light irradiation, thereby increasing resistance of the n-type group-13 nitride semiconductor.

2. The method of producing an n-type group-13 nitride semiconductor according to claim 1, wherein a density of energy being irradiated is 10 mJ/cm² or more to 200 mJ/cm² or less.

3. A method of forming a current confinement structure, comprising:
preparing a layer comprising an n-type group-13 nitride semiconductor; and
irradiating a region of the layer comprising an n-type group-13 nitride semiconductor, which is to be a current confinement portion, with light having a wavelength of 350 nm or more to 370 nm or less, wherein the current confinement portion has resistance higher than that of the current confinement opening as region through which current is injected into an active layer and the crystal structure is not changed after the light irradiation.

4. A method of producing a surface emitting laser using a current confinement structure fabricated by the method according to claim 3, comprising:
preparing, on a substrate,
an n-type DBR layer;
a quantum well active layer;
a current confinement layer having the current confinement structure; and
an n-type contact layer.

5. The method of producing a surface emitting laser according to claim 4, wherein a thickness of the current confinement layer is 100 nm or more to 1000 nm or less.

6. The method of producing a surface emitting laser according to claim 4, wherein a wavelength of the light irradiation is equal to or longer than a forbidden band wavelength of a contact layer and equal to or shorter than a forbidden band wavelength of the current confinement layer when the current confinement layer comprises an n-type AlₓGa₁₋ₓN (0≦x<0.4) and the n-type contact layer comprises an n-type Al_{x′}Ga_{1-x′}N (0≦x′<0.4 and x<x′).

7. The method of producing a surface emitting laser according to claim 4, wherein the forbidden band wavelength of the current confinement layer is shorter than a forbidden band wavelength converted by band gap εg(Γ) of the following equation (1) and the forbidden band wavelength of the contact layer is longer than the forbidden band wavelength converted by band gap εg(Γ) of the following equation (2),
εg(Γ)=3.39+1.81x+bx²(b=1.0+0.3, 0≦x≦0.4) (1)
εg(Γ)=3.39+1.81x′+bx′²(b=1.0±0.3, 0<x′≦0.4) (2).

8. A method of producing a semiconductor laser, comprising:
preparing, on a substrate, a member comprising a first mirror, an active layer and an n-type group-13 nitride semiconductor layer;
irradiating the n-type group-13 nitride semiconductor layer with light having a wavelength of 350 nm or more to 370 nm or less to form a current confinement region; and
forming a second mirror on the n-type group-13 nitride semiconductor layer.
